(19) United States
(12) Patent Application Publication
(10) Pub. No.: US 2025/0226325 A1
(43) Pub. Date: Jul. 10, 2025

(54) PACKAGE STRUCTURE AND MANUFACTURING METHOD THEREOF

(71) Applicant: Chung W. Ho, Taipei City (TW)

(72) Inventor: Chung W. Ho, Taipei City (TW)

(21) Appl. No.: 18/780,485

(22) Filed: Jul. 23, 2024

(30) Foreign Application Priority Data
Jan. 4, 2024 (TW) 113100485

(51) Int. Cl. H01L 23/538; H01L 21/48; H01L 23/00; H01L 25/065

(52) U.S. Cl. CPC H01L 23/5385; H01L 21/4857; H01L 23/562; H01L 25/0655; H01L 24/16; H01L 2224/16227

(57) ABSTRACT

A package structure includes a multi-layer circuit layer, multiple components, and a stress adjustment board. The multi-layer circuit layer has a first surface and a second surface opposite to each other. The components are configured on the first surface of the multi-layer circuit layer and electrically connected to the multi-layer circuit layer. The stress adjustment board is configured on the second surface of the multi-layer circuit layer. The stress adjustment board includes a copper layer and has multiple conductive vias. The conductive vias are electrically connected to the multi-layer circuit layer. A first peripheral surface of the multi-layer circuit layer is aligned with a second peripheral surface of the stress adjustment board.

### CROSS-REFERENCE TO RELATED APPLICATION

This application claims the priority benefit of Taiwan application serial no. 113100485, filed on Jan. 4, 2024. The entirety of the above-mentioned patent application is hereby incorporated by reference herein and made a part of this specification.

### BACKGROUND

### Technical Field

The disclosure relates to a semiconductor structure and a manufacturing method thereof. and in particular to a package structure and a manufacturing method thereof.

### Description of Related Art

Regarding the design of package structures, the component area utilization rate of silicon interposers is significantly greater than that of organic substrates due to a.) substrate warpage, as the thermal expansion coefficient mismatch between silicon interposers and organic substrates leads to greater warpage with larger elements, and b.) circuit density, as smaller circuits require less space for fanning out and interconnection, thus having smaller areas. Therefore, in the prior art, the area of the organic substrate is greater than the area of the silicon interposer. In addition, the thickness of the organic substrate significantly increases to resist the stress applied to the substrate due to changes in temperature differences, with the resistance being a cubed value of the thickness.

### SUMMARY

The disclosure provides a package structure and a manufacturing method thereof, which effectively mitigate board warpage and increase structural reliability.

A package structure of the disclosure includes a multi-layer circuit layer, multiple components, and a stress adjustment board. The multi-layer circuit layer has a first surface and a second surface opposite to each other. The components are configured on the first surface of the multi-layer circuit layer and electrically connected to the multi-layer circuit layer. The stress adjustment board is configured on the second surface of the multi-layer circuit layer. The stress adjustment board is a substrate with no trace copper layers and dielectric layers and has multiple conductive vias. The conductive vias are electrically connected to the multi-layer circuit layer. A first peripheral surface of the multi-layer circuit layer is aligned with a second peripheral surface of the stress adjustment board.

In an embodiment of the disclosure, an orthogonal projection area of the components on the multi-layer circuit layer is at least greater than 70% of an area of the multi-layer circuit layer.

In an embodiment of the disclosure, the package structure further includes a support plate configured on the first surface of the multi-layer circuit layer. The support plate has multiple openings, and the components are respectively configured in the openings. An orthogonal projection area of the components on the multi-layer circuit layer, combined with an orthogonal projection area of the support plate on the multi-layer circuit layer, is at least greater than 80% of an area of the multi-layer circuit layer.

In an embodiment of the disclosure, a material of the support plate includes copper, copper alloy, stainless steel, or stainless steel alloy.

In an embodiment of the disclosure, the multi-layer circuit layer includes multiple dielectric layers, multiple patterned circuit layers, and multiple conductive blind vias. The dielectric layers and the patterned circuit layers are alternately configured, and two adjacent patterned circuit layers are electrically connected through the conductive blind vias.

In an embodiment of the disclosure, a material of each of the dielectric layers includes polyimide (PI), Ajinomoto build-up films (ABF), or benzocyclobutene (BCB).

In an embodiment of the disclosure, the material of each of the dielectric layers includes pre-pregs, and the material of each of the conductive vias includes copper.

A manufacturing method of a package structure of the disclosure includes the following steps. A multi-layer circuit layer is formed on a substrate. The multi-layer circuit layer has a first surface and a second surface opposite to each other. The first surface of the multi-layer circuit layer is configured on the substrate. A stress adjustment board is formed on the second surface of the multi-layer circuit layer. The stress adjustment board includes no trace copper layers and dielectric layers and has multiple conductive vias. The conductive vias are electrically connected to the multi-layer circuit layer. A first peripheral surface of the multi-layer circuit layer is aligned with a second peripheral surface of the stress adjustment board. The substrate is removed to expose the first surface of the multi-layer circuit layer. Multiple components are configured on the first surface of the multi-layer circuit layer. The components are electrically connected to the multi-layer circuit layer.

In an embodiment of the disclosure, before configuring the components on the first surface of the multi-layer circuit layer, a support plate is configured on the first surface of the multi-layer circuit layer. The support plate has multiple openings, and the components are respectively configured in the openings. An orthogonal projection area of the components on the multi-layer circuit layer, combined with an orthogonal projection area of the support plate on the multi-layer circuit layer, is at least greater than 80% of an area of the multi-layer circuit layer.

Based on the above, in the design of the package structure of the disclosure, the components and the stress adjustment board are respectively configured on surfaces on two opposite sides of the multi-layer circuit layer, and the first peripheral surface of the multi-layer circuit layer is aligned with the second peripheral surface of the stress adjustment board. That is, the disclosure reaches a stress balance for the board warpage, which occurs after the components are configured in the multi-layer circuit layer, through the stress adjustment board of the same size as the multi-layer circuit layer. In short, through the disposition of the stress adjustment board, board warpage can be effectively mitigated and structural reliability can be increased for the package structure of the disclosure.

To make the aforementioned features and advantages of the disclosure more apparent and comprehensible, several embodiments accompanied with drawings are described in detail as follows.

### BRIEF DESCRIPTION OF THE DRAWINGS

FIGS. 1A to 1C are schematic cross-sectional diagrams of a manufacturing method of a package structure according to an embodiment of the disclosure.

FIGS. 2A and 2B are schematic cross-sectional diagrams of a part of the steps of a manufacturing method of a package structure according to another embodiment of the disclosure.

### DESCRIPTION OF THE EMBODIMENTS

The embodiments of the disclosure may be understood together with drawings, and the drawings of the disclosure are also regarded as a part of description of the disclosure. It should be understood that the drawings of the disclosure are not drawn to scale and, in fact, the dimensions of elements may be arbitrarily enlarged or reduced in order to clearly represent the features of the disclosure.

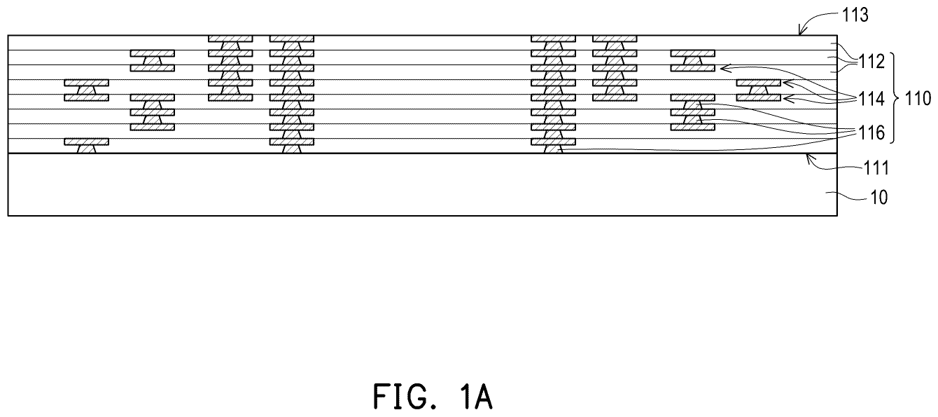

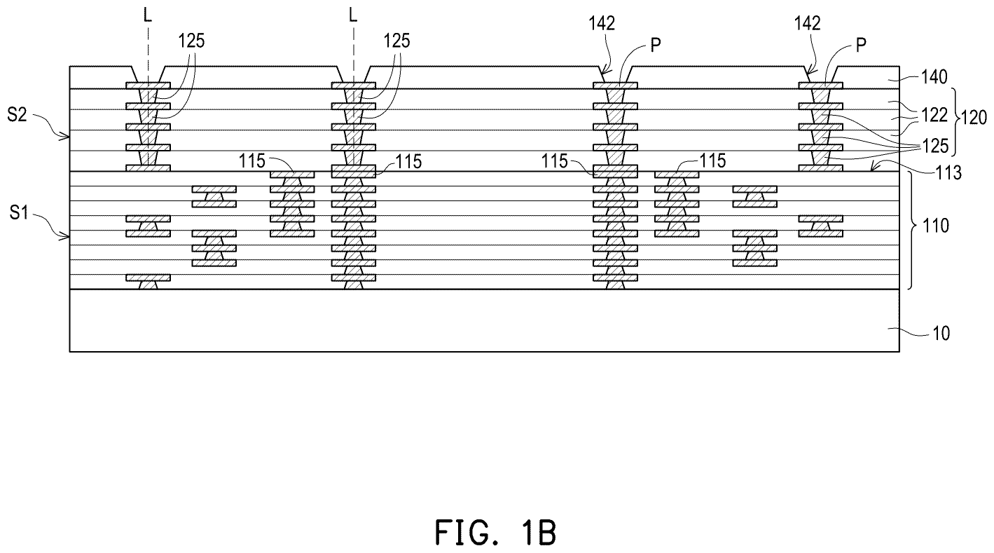

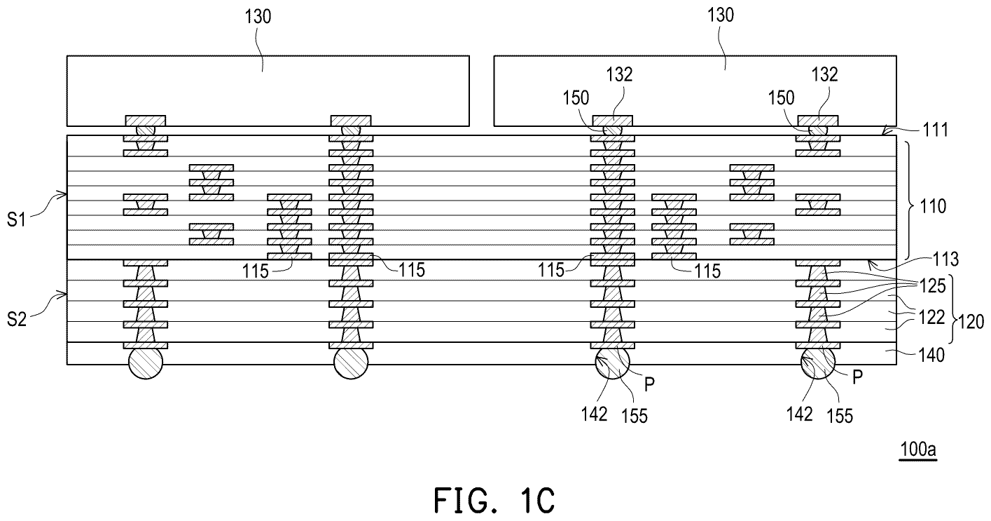

FIGS. 1A to 1C are schematic cross-sectional diagrams of a manufacturing method of a package structure according to an embodiment of the disclosure. For the manufacturing method of the package structure in this embodiment, please refer to FIG. 1A first. A multi-layer circuit layer 110 is formed on a substrate 10. The multi-layer circuit layer 110 has a first surface 111 and a second surface 113 opposite to each other. The first surface 111 of the multi-layer circuit layer 110 is configured on the substrate 10.

In an embodiment, the substrate 10 is, for example, a glass substrate, a pre-preg (PP) substrate, a stainless steel substrate, or another smooth substrate with supporting capability, but is not limited thereto. The multi-layer circuit layer 110 may include multiple dielectric layers 112, multiple patterned circuit layers 114, and multiple conductive blind vias 116. The dielectric layers 112 and the patterned circuit layers 114 are alternately configured, and two adjacent patterned circuit layers 114 are electrically connected through the conductive blind vias 116. In an embodiment, the material of the dielectric layer 112 includes polyimide (PI), Ajinomoto build-up films (ABF), or benzocyclobutene (BCB), but is not limited thereto. The material of the patterned circuit layer 114 and the conductive blind via 116 may be, for example, copper, but is not limited thereto.

Next, referring to FIG. 1B, a stress adjustment board 120 is formed on the second surface 113 of the multi-layer circuit layer 110. This may be realized by filling conductive paste in the through holes of a bonding film after laser drill, and then attaching the stress adjustment board 120 to the multi-layer circuit layer 110 through thermal compression, wherein the stress adjustment board 120 docks with a corresponding pad 115 on the multi-layer circuit layer 110. The stress adjustment board 120 includes copper layers and dielectric layers 122 and has multiple conductive vias 125. The conductive vias 125 are electrically connected to the multi-layer circuit layer 110.

Furthermore, in this embodiment, the conductive vias 125 of the stress adjustment board 120 are configured in the dielectric layer 122 and are electrically connected to each other. In an embodiment, the conductive vias 125 of the stress adjustment board 120 may be arranged in the dielectric layer 122 along a straight line L, but are not limited thereto. In an embodiment, the material of the dielectric layer 122 is, for example, PP or other materials with a low coefficient of thermal expansion (CTE). Here, the low CTE is, for example, a CTE of 1 ppm/K to 3 ppm/K, but is not limited thereto. The material of the conductive via 125 is, for example, copper, but is not limited thereto. Preferably, a first peripheral surface S1 of the multi-layer circuit layer 110 is aligned with a second peripheral surface S2 of the stress adjustment board 120. That is, the size of the stress adjustment board 120 in this embodiment is the same as the size of the multi-layer circuit layer 110. Herein, the size may include length, width, and/or area. In an embodiment, the multi-layer circuit layer 110 and the stress adjustment board 120 may be deemed a coreless substrate.

Next, referring to FIG. 1B again, a solder mask layer 140 is formed on the stress adjustment board 120. The solder mask layer 140 has multiple solder mask openings 142. The solder mask openings 142 expose a part of the conductive vias 125, thereby defining multiple conductive via pads P.

It should be noted that, although a structural layer is only formed on a surface on one side of the substrate 10 through the manufacturing method in the above embodiments, the disclosure is not limited thereto. In other unshown embodiments, structural layers may also be formed on the surfaces on two opposite sides of the substrate 10. This still falls within the intended scope of the disclosure.

Next, referring to FIGS. 1B and 1C at the same time, the substrate 10 is removed and the structure is flipped upside down to expose the first surface 111 of the multi-layer circuit layer 110.

Finally, referring to FIG. 1C again, multiple components 130 are configured on the first surface 111 of the multi-layer circuit layer 110. An component pad 132 of the component 130 is electrically connected to the multi-layer circuit layer 110 through a solder ball 150. In an embodiment, the component 130 may be, for example, an active component or a passive component. The active component is, for example, single-chip or multiple-chip, and the passive component is, for example, a resistor or a capacitor. However, the disclosure is not limited thereto. In an embodiment, the component 130 is electrically connected to the multi-layer circuit layer 110 through a flip-chip method. Preferably, an orthogonal projection area of the components 130 on the multi-layer circuit layer 110 is at least greater than 70% of an area of the multi-layer circuit layer 110, providing a higher space utilization rate. In an embodiment, an orthogonal projection area of the chips and passive components on the multi-layer circuit layer 110 is at least greater than 70% of the area of the multi-layer circuit layer 110. In addition, in order to form an electrical connection with an external circuit, a solder ball 155 may be formed on the conductive via pad P. The conductive via pad P may be electrically connected to the external circuit through the solder ball 155. At this stage, the manufacture of a package structure 100a is completed.

In terms of structure, please refer to FIG. 1C again. In this embodiment, the package structure 100a includes the multi-layer circuit layer 110, the component 130, and the stress adjustment board 120. The multi-layer circuit layer 110 has the first surface 111 and the second surface 113 opposite to each other. The component 130 is configured on the first surface 111 of the multi-layer circuit layer 110 and electrically connected to the multi-layer circuit layer 110. The stress adjustment board 120 is configured on the second surface 113 of the multi-layer circuit layer 110. The stress adjustment board 120 includes copper layers, dielectric layers and the conductive via 125. The conductive via 125 is electrically connected to the multi-layer circuit layer 110. The first peripheral surface S1 of the multi-layer circuit layer 110 is aligned with the second peripheral surface S2 of the stress adjustment board 120. Preferably, the orthogonal projection area of the components 130 on the multi-layer circuit layer 110 is at least greater than 70% of the area of the multi-layer circuit layer 110. In an embodiment, the orthogonal projection area of the chips and passive components (not shown) on the multi-layer circuit layer 110 is at least greater than 70% of the area of the multi-layer circuit layer 110. Other than transmitting signals and electricity through the conductive via 125, the stress adjustment board 120 effectively balances the stress generated after the component 130 is configured on the multi-layer circuit layer 110 by selecting materials with a low CTE. That is, in this embodiment, stress balance is achieved for the board warpage, which occurs after the component 130 is configured in the multi-layer circuit layer 110, through the stress adjustment board 120 of the same size as the multi-layer circuit layer 110. In short, through the disposition of the stress adjustment board 120, board warpage can be effectively mitigated and structural reliability can be increased for the package structure 100a in this embodiment.

It must be noted that the reference numerals and part of the content of the above embodiments are adopted in the following embodiments, wherein the same reference numerals are used to represent the same or similar elements, and the description of the same technical content is omitted. Reference may be made to the above embodiments for the description of the omitted part, which will not be repeated in the following embodiments.

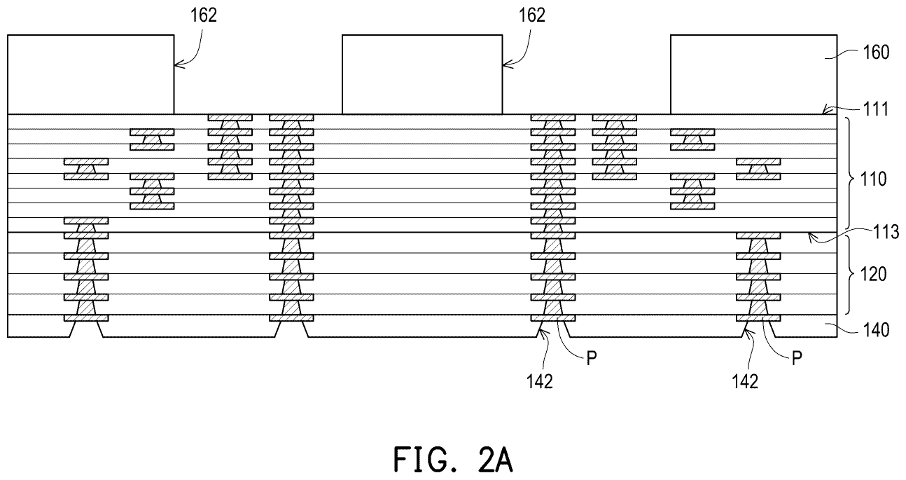

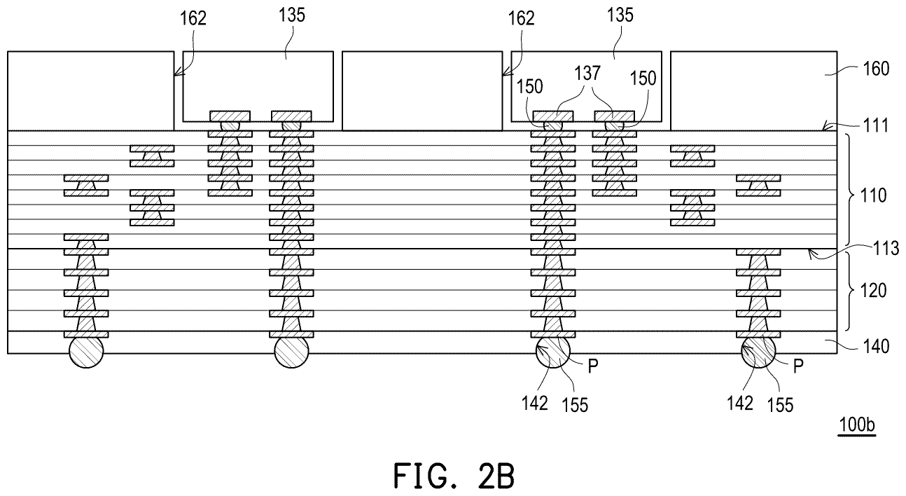

FIGS. 2A and 2B are schematic cross-sectional diagrams of a part of the steps of a manufacturing method of a package structure according to another embodiment of the disclosure. Referring to FIGS. 1B and 2A at the same time, the manufacturing method of the package structure in this embodiment is similar to the manufacturing method of the package structure described above, with the main difference being that, in this embodiment, after removing the substrate 10 and exposing the first surface 111 of the multi-layer circuit layer 110, a support plate 160 is configured on the first surface 111 of the multi-layer circuit layer 110. The support plate 160 has multiple openings 162. The openings 162 expose a part of the multi-layer circuit layer 110. In an embodiment, the material of the support plate 160 is, for example, copper, copper alloy, stainless steel, or stainless steel alloy, but is not limited thereto.

Thereafter, referring to FIG. 2B, multiple components 135 are configured on the first surface 111 of the multi-layer circuit layer 110. The components 135 are respectively configured in the openings 162 of the support plate 160. The component pad 137 of the component 135 is electrically connected to the multi-layer circuit layer 110 through the solder ball 150. That is, the component 135 and the support plate 160 are disposed on the same side and the same surface (i.e., the first surface 111) of the multi-layer circuit layer 110. Preferably, the orthogonal projection area of the components 135 on the multi-layer circuit layer 110, combined with the orthogonal projection area of the support plate 160 on the multi-layer circuit layer 110, is at least greater than 80% of the area of the multi-layer circuit layer 110. That is, the area of the support plate 160 compensates for the insufficient area of the components 135. In an embodiment, the orthogonal projection area of the components 135 and passive components (not shown) on the multi-layer circuit layer 110, combined with the orthogonal projection area of the support plate 160 on the multi-layer circuit layer 110, is at least greater than 80% of the area of the multi-layer circuit layer 110. At this stage, the manufacture of a package structure 100b is completed.

In terms of structure, please refer to FIGS. 1C and 2B at the same time. The package structure 100b in this embodiment is similar to the package structure 100a described above, with the main difference being that, in this embodiment, since the orthogonal projection area of the components 135 on the multi-layer circuit layer 110 is greater than 70% of the area of the multi-layer circuit layer 110, the package structure 100b in this embodiment further includes the support plate 160 configured on the first surface 111 of the multi-layer circuit layer 110. The support plate 160 has multiple openings 162, and the components 135 are respectively configured in the openings 162. Preferably, the orthogonal projection area of the components 135 on the multi-layer circuit layer 110, combined with the orthogonal projection area of the support plate 160 on the multi-layer circuit layer 110, is at least greater than 80% of the area of the multi-layer circuit layer 110. Stress balance is achieved for board warpage, which occurs after the component 135 is configured in the multi-layer circuit layer 110, through the disposition of the support plate 160 and the stress adjustment board 120 of the same size as the multi-layer circuit layer 110. In short, through the disposition of the stress adjustment board 120 and the support plate 160, board warpage can be effectively mitigated and structural reliability can be increased for the package structure 100b in this embodiment.

In summary, in the design of the package structure of the disclosure, the components and the stress adjustment board are respectively configured on surfaces on two opposite sides of the multi-layer circuit layer, and the first peripheral surface of the multi-layer circuit layer is aligned with the second peripheral surface of the stress adjustment board. That is, the disclosure reaches a stress balance for the board warpage, which occurs after the components are configured in the multi-layer circuit layer, through the stress adjustment board of the same size as the multi-layer circuit layer. In short, through the disposition of the stress adjustment board, board warpage can be effectively mitigated and structural reliability can be increased for the package structure of the disclosure.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A package structure, comprising:
a multi-layer circuit layer, having a first surface and a second surface opposite to each other;
a plurality of components, configured on the first surface of the multi-layer circuit layer and electrically connected to the multi-layer circuit layer; and
a stress adjustment board, configured on the second surface of the multi-layer circuit layer, wherein the stress adjustment board comprises no trace copper layers and dielectric layers and has a plurality of conductive vias, the plurality of conductive vias being electrically connected to the multi-layer circuit layer, wherein a first peripheral surface of the multi-layer circuit layer is aligned with a second peripheral surface of the stress adjustment board.

2. The package structure of claim 1, wherein an orthogonal projection area of the plurality of components on the multi-layer circuit layer is at least greater than 70% of an area of the multi-layer circuit layer.

3. The package structure of claim 1, further comprising:
a support plate, configured on the first surface of the multi-layer circuit layer, the support plate having a plurality of openings, wherein the plurality of components are respectively configured in the plurality of openings, and an orthogonal projection area of the plurality of components on the multi-layer circuit layer, combined with an orthogonal projection area of the support plate on the multi-layer circuit layer, is at least greater than 80% of an area of the multi-layer circuit layer.

4. The package structure of claim 3, wherein a material of the support plate comprises a copper, a copper alloy, a stainless steel, or a stainless steel alloy.

5. The package structure of claim 1, wherein the multi-layer circuit layer comprises a plurality of dielectric layers, a plurality of patterned circuit layers, and a plurality of conductive blind vias, wherein the plurality of dielectric layers and the plurality of patterned circuit layers are alternately configured, and two adjacent patterned circuit layers of the plurality of patterned circuit layers are electrically connected through the plurality of conductive blind vias.

6. The package structure of claim 5, wherein a material of each of the plurality of dielectric layers comprises a polyimide, an Ajinomoto build-up film, or a benzocyclobutene.

7. The package structure of claim 1, wherein a material of each of the dielectric layers comprises a pre-preg, and a material of each of the plurality of conductive vias comprises a copper.

8. A manufacturing method of a package structure, comprising:
forming a multi-layer circuit layer on a substrate, the multi-layer circuit layer having a first surface and a second surface opposite to each other, wherein the first surface of the multi-layer circuit layer is configured on the substrate;
forming a stress adjustment board configured on the second surface of the multi-layer circuit layer, wherein the stress adjustment board comprises no trace copper and dielectric layers and has a plurality of conductive vias, the plurality of conductive vias being electrically connected to the multi-layer circuit layer, wherein a first peripheral surface of the multi-layer circuit layer is aligned with a second peripheral surface of the stress adjustment board;
removing the substrate to expose the first surface of the multi-layer circuit layer; and
configuring a plurality of components on the first surface of the multi-layer circuit layer, the plurality of components being electrically connected to the multi-layer circuit layer.

9. The manufacturing method of the package structure of claim 8, further comprising:
before configuring the plurality of components on the first surface of the multi-layer circuit layer, configuring a support plate on the first surface of the multi-layer circuit layer, the support plate having a plurality of openings, wherein the plurality of components are respectively configured in the plurality of openings, and an orthogonal projection area of the plurality of components on the multi-layer circuit layer, combined with an orthogonal projection area of the support plate on the multi-layer circuit layer, is at least greater than 80% of an area of the multi-layer circuit layer.
